(19) United States
(12) Patent Application Publication
(10) Pub. No.: US 2026/0025899 A1
(43) Pub. Date: Jan. 22, 2026

(54) EXTREME ULTRAVIOLET LIGHT GENERATION SYSTEM, CONTROL METHOD OF EXTREME ULTRAVIOLET LIGHT GENERATION SYSTEM, AND ELECTRONIC DEVICE MANUFACTURING METHOD

(71) Applicant: Gigaphoton Inc., Tochigi (JP)

(72) Inventors: Yuichi NISHIMURA, Oyama-shi (JP); Yoshifumi UENO, Oyama-shi (JP)

(73) Assignee: Gigaphoton Inc., Tochigi (JP)

(21) Appl. No.: 19/231,016

(22) Filed: Jun. 6, 2025

(30) Foreign Application Priority Data
Jul. 19, 2024 (JP) 2024-116227

(51) Int. Cl. H05G 2/00; G03F 1/84; G03F 7/00

(52) U.S. Cl. CPC H05G 2/0086; G03F 1/84; G03F 7/70033; G03F 7/7055

(57) ABSTRACT

Provided is a control method of an extreme ultraviolet light generation system. The extreme ultraviolet light generation system includes a target supply unit configured to supply a target, a laser device configured to irradiate the target with laser light, an EUV energy sensor configured to detect an energy of extreme ultraviolet light generated by the target being irradiated with the laser light, an optical adjuster configured to adjust an energy of the laser light, and a processor configured to adjust the optical adjuster by PID control based on output of the EUV energy sensor. The processor acquires a first index value for the output of the EUV energy sensor and a second index value different from the first index value and determines a control gain in the PID control based on the first and second index values.

### CROSS-REFERENCE TO RELATED APPLICATIONS

The present application claims the benefit of Japanese Patent Application No. 2024-116227, filed on Jul. 19, 2024, the entire contents of which are hereby incorporated by reference.

### BACKGROUND

### 1. Technical Field

The present disclosure relates to an extreme ultraviolet light generation system, a control method of the extreme ultraviolet light generation system, and an electronic device manufacturing method.

### 2. Related Art

Recently, miniaturization of a transfer pattern in optical lithography of a semiconductor process has been rapidly proceeding along with miniaturization of the semiconductor the next generation, process. In microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2020/0067259

Patent Document 2: US Patent Application Publication No. 2022/0110205

### SUMMARY

According to an aspect of the present disclosure, provided is a control method of an extreme ultraviolet light generation system. The extreme ultraviolet light generation system includes a target supply unit configured to supply a target, a laser device configured to irradiate the target with laser light, an EUV energy sensor configured to detect an energy of extreme ultraviolet light generated by the target being irradiated with the laser light, an optical adjuster configured to adjust an energy of the laser light, and a processor configured to adjust the optical adjuster by PID control based on output of the EUV energy sensor. The processor acquires a first index value for the output of the EUV energy sensor and a second index value different from the first index value and determines a control gain in the PID control based on the first and second index values.

An extreme ultraviolet light generation system according to an aspect of the present disclosure includes a target supply unit configured to supply a target, a laser device configured to irradiate the target with laser light, an EUV energy sensor configured to detect an energy of extreme ultraviolet light generated by the target being irradiated with the laser light, an optical adjuster configured to adjust an energy of the laser light, and a processor configured to adjust the optical adjuster by PID control based on output of the EUV energy sensor. The processor acquires a first index value for the output of the EUV energy sensor and a second index value different from the first index value and determines a control gain in the PID control based on the first and second index values.

An electronic device manufacturing method according to an aspect of the present disclosure includes generating extreme ultraviolet light using an extreme ultraviolet light generation system, outputting the extreme ultraviolet light to an exposure apparatus, and exposing a photosensitive substrate to the extreme ultraviolet light in the exposure apparatus to manufacture an electronic device. Here, the extreme ultraviolet light generation system includes a target supply unit configured to supply a target, a laser device configured to irradiate the target with laser light, an EUV energy sensor configured to detect an energy of the extreme ultraviolet light generated by the target being irradiated with the laser light, an optical adjuster configured to adjust an energy of the laser light, and a processor configured to adjust the optical adjuster by PID control based on output of the EUV energy sensor. The processor acquires a first index value for the output of the EUV energy sensor and a second index value different from the first index value and determines a control gain in the PID control based on the first and second index values.

An electronic device manufacturing method according to an aspect of the present disclosure includes inspecting a defect of a mask by irradiating the mask with extreme ultraviolet light generated by an extreme ultraviolet light generation system, selecting a mask using a result of the inspection, and exposing and transferring a pattern formed on the selected mask onto a photosensitive substrate. Here, the extreme ultraviolet light generation system includes a target supply unit configured to supply a target, a laser device configured to irradiate the target with laser light, an EUV energy sensor configured to detect an energy of the extreme ultraviolet light generated by the target being irradiated with the laser light, an optical adjuster configured to adjust an energy of the laser light, and a processor configured to adjust the optical adjuster by PID control based on output of the EUV energy sensor. The processor acquires a first index value for the output of the EUV energy sensor and a second index value different from the first index value and determines a control gain in the PID control based on the first and second index values.

### BRIEF DESCRIPTION OF THE DRAWINGS

Embodiments of the present disclosure will be described below merely as examples with reference to the accompanying drawings.

FIG. 1 shows the configuration of an LPP EUV light generation system.

FIG. 2 shows the configuration of the EUV light generation system according to a comparative example.

FIG. 3 is a block diagram of energy control of EUV light according to the comparative example.

FIG. 4 is a flowchart of control gain determination in the energy control of the EUV light in the comparative example.

FIG. 5 is a graph showing the relationship between the integral gain set in the comparative example, and the deviation and the variation of the energy of the EUV light.

FIG. 6 is a flowchart of control gain determination in the energy control of the EUV light in a first embodiment.

FIG. 7 is a graph showing the relationship between the integral gain set in the first embodiment, and the deviation and the variation of the energy of the EUV light.

FIG. 8 is a graph showing the relationship between the integral gain set in a second embodiment, and the deviation and the variation of the energy of the EUV light.

FIG. 9 shows the configuration of an exposure apparatus connected to the EUV light generation system.

FIG. 10 shows the configuration of an inspection apparatus connected to the EUV light generation system.

### DESCRIPTION OF EMBODIMENTS

### Contents

1. Overall description of EUV light generation system 11
1.1 Configuration
1.2 Operation
   2. Comparative example
2.1 Configuration
2.2 Operation
2.3 Problem of comparative example
   3. EUV light generation system 11a determining control gain in consideration of variation 3σ of energy E_{EUV} of EUV light
3.1 Configuration and operation
3.2 Modification
3.3 Effect
   4. EUV light generation system 11a determining control gain to minimize deviation Ed of energy E_{EUV} of EUV light
4.1 Configuration and operation
4.2 Effect
   5. Timing of control gain determination processing

### 6. Others

6.1 Example of EUV light utilization apparatus 6
6.2 Processor 5
6.3 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Overall Description of EUV Light Generation System 11

### 1.1 Configuration

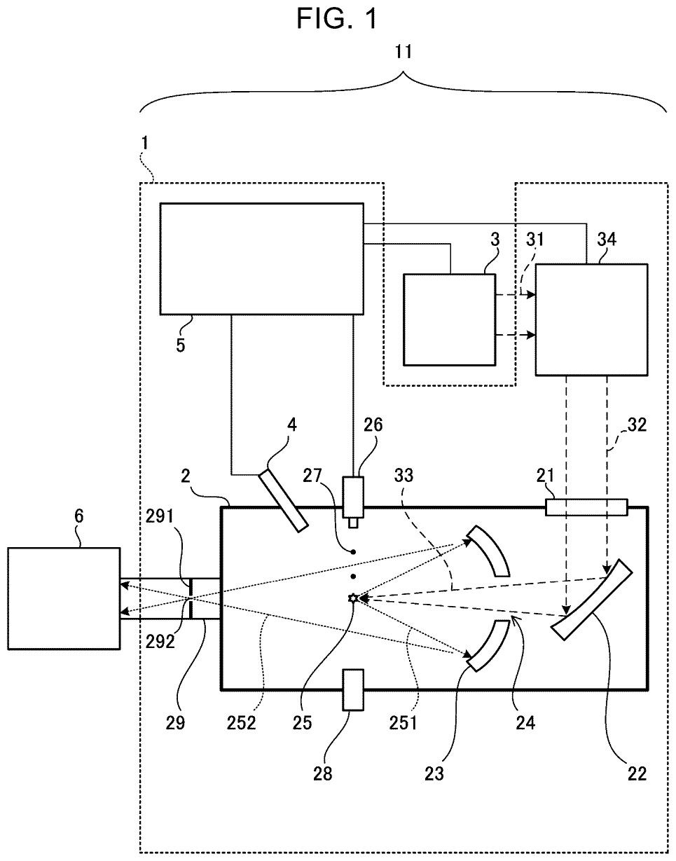

FIG. 1 shows the configuration of an LPP EUV light generation system 11. An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2 and a target supply unit 26. The chamber 2 is a sealable container. The target supply unit 26 supplies a target 27 containing a target substance into the chamber 2. The material of the target substance may include tin, terbium, gadolinium, lithium, xenon, or a combination of any two or more thereof.

A through hole is formed in a wall of the chamber 2. The through hole is blocked by a window 21 and laser light 32 output from the laser device 3 is transmitted through the window 21. An EUV light concentrating mirror 23 having a spheroidal reflection surface is arranged in the chamber 2. The EUV light concentrating mirror 23 has first and second focal points. A multilayer reflection film in which molybdenum and silicon are alternately stacked is formed on a surface of the EUV light concentrating mirror 23. The EUV light concentrating mirror 23 is arranged such that the first focal point is located in a plasma generation region 25 and the second focal point is located at an intermediate focal point 292. A through hole 24 is formed at the center of the EUV light concentrating mirror 23, and laser light 33 passes through the through hole 24.

The EUV light generation apparatus 1 includes a processor 5, a target sensor 4, and the like. The configuration of the processor 5 will be described later. The target sensor 4 detects at least one of the presence, trajectory, position, and velocity of the target 27. The target sensor 4 may have an imaging function.

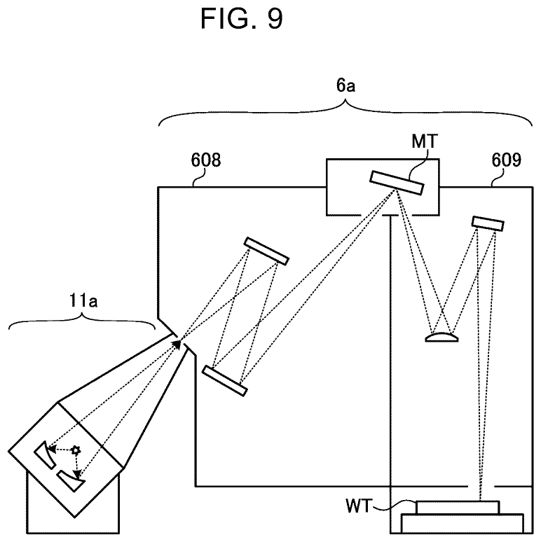

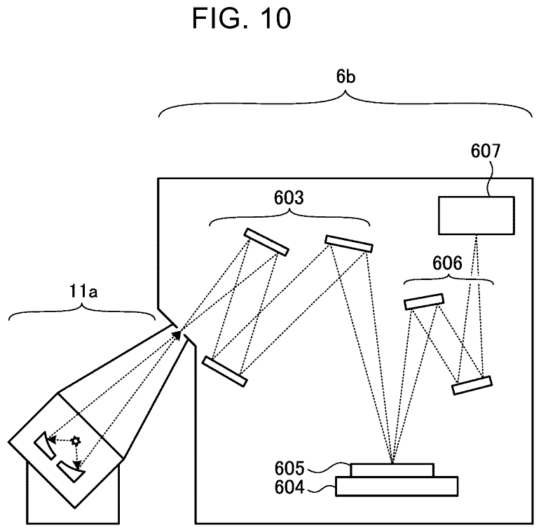

Further, the EUV light generation apparatus 1 includes a connection portion 29 providing communication between the internal space of the chamber 2 and the internal space of an EUV light utilization apparatus 6. The EUV light utilization apparatus 6 may be an exposure apparatus 6a shown in FIG. 9 or an inspection apparatus 6b shown in FIG. 10. A wall 291 in which an aperture is formed is arranged in the connection portion 29. The wall 291 is arranged such that the aperture is located at the second focal point of the EUV light concentrating mirror 23.

Further, the EUV light generation apparatus 1 includes a laser light transmission device 34, a laser light concentrating mirror 22, a target collection unit 28 for collecting the target 27, and the like. The laser light transmission device 34 includes an optical element for defining a transmission state of the laser light 32, and an actuator for adjusting the position, posture, and the like of the optical element.

### 1.2 Operation

Operation of the EUV light generation system 11 will be described with reference to FIG. 1. Pulse laser light 31 output from the laser device 3 enters, via the laser light transmission device 34, the chamber 2 through the window 21 as the laser light 32. The laser light 32 travels along a laser light path in the chamber 2, is reflected by the laser light concentrating mirror 22, and is radiated to the target 27 as the laser light 33.

The target supply unit 26 outputs the target 27 toward the plasma generation region 25 in the chamber 2. The target 27 is irradiated with the laser light 33. The target 27 irradiated with the laser light 33 is turned into plasma, and radiation light 251 is radiated from the plasma. EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6.

One target 27 may be irradiated with a plurality of pulses included in the laser light 33. In this case, for example, the laser device 3 includes a prepulse laser (not shown) and a main pulse laser (not shown). Prepulse laser light output from the prepulse laser has a lower energy than main pulse laser light output from the main pulse laser. The target 27 is diffused by irradiation with the prepulse laser light. The diffused target 27 is turned into plasma by irradiation with the main pulse laser light.

The processor 5 controls the entire EUV light generation system 11. The processor 5 processes a detection result of the target sensor 4. Based on the detection result of the target sensor 4, the processor 5 controls the timing at which the target 27 is output, the output direction of the target 27, and the like. Further, the processor 5 controls oscillation timing of the laser device 3, the travel direction of the laser light 32, the concentration position of the laser light 33, and the like. The above-described various kinds of control are merely examples, and other control may be added as necessary.

### 2. Comparative Example

### 2.1 Configuration

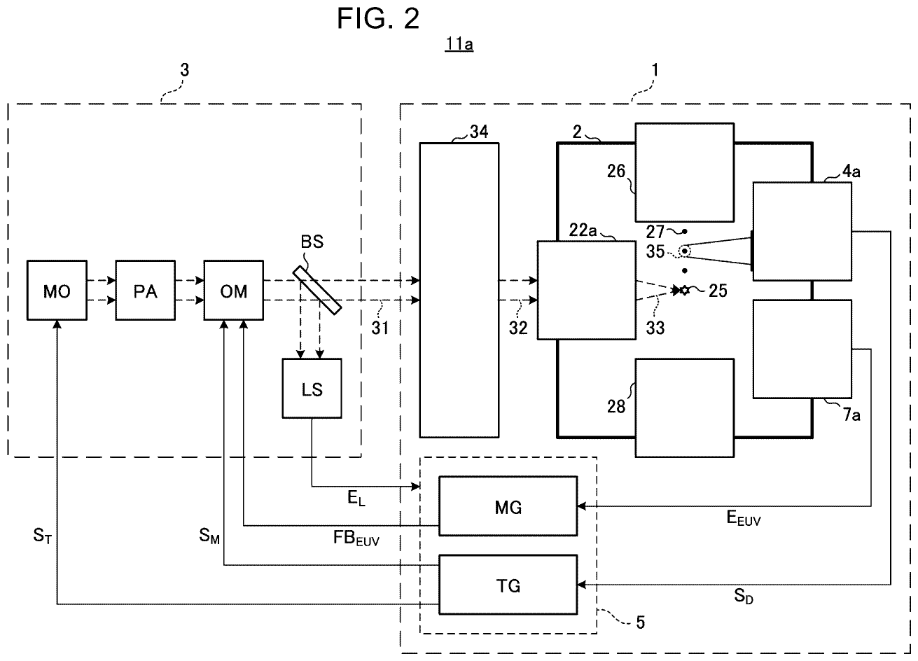

FIG. 2 shows the configuration of an EUV light generation system 11a according to a comparative example. The comparative example of the present disclosure is an example recognized by the applicant as known only by the applicant, and is not a publicly known example admitted by the applicant.

In the EUV light generation system 11a according to the comparative example, the laser device 3 includes a master oscillator MO, an amplifier PA, an optical modulator OM, a beam splitter BS, and a laser energy sensor LS. The amplifier PA is arranged on the optical path of the laser light output from the master oscillator MO.

The optical modulator OM is arranged on the optical path of the laser light output from the amplifier PA. The optical modulator OM is an example of the optical adjuster in the present disclosure. The optical adjuster may be included in the laser device 3. The optical modulator OM includes an acoustic optical element (not shown) and transmittance of the laser light is controlled by an application voltage applied to the acoustic optical element. The optical modulator OM may include an electric optical element or an attenuator instead of the acoustic optical element, and the transmittance of the laser light may be controlled by the application voltage to the electric optical element or the attenuator. In the present disclosure, the application voltage applied to the acoustic optical element, the electric optical element, or the attenuator is referred to as the application voltage of the optical modulator OM.

As another example of the optical adjuster according to the present disclosure, a mechanism (not shown) for changing the excitation intensity of the master oscillator MO or the amplification efficiency of the amplifier PA may be provided instead of the optical modulator OM. Such a mechanism may be a mechanism for adjusting a current supplied to a pumping lamp for exciting a laser crystal, for example, when the master oscillator MO or the amplifier PA is a solid-state laser.

In FIG. 2, the beam splitter BS is arranged on the optical path of the laser light output from the optical modulator OM. The beam splitter BS transmits a part of the laser light as the laser light 31 at high transmittance and reflects the other part. The laser energy sensor LS is arranged on the optical path of the laser light reflected by the beam splitter BS, and detects an energy E_{L} of the laser light and outputs to the processor 5.

A target timing sensor 4a, an EUV energy sensor 7a, and a laser light concentrating optical system 22a are arranged in the chamber 2. The target timing sensor 4a includes a light source (not shown), a transfer optical system (not shown), and an optical sensor (not shown). The light source illuminates the target 27 having reached a detection region 35 between the target supply unit 26 and the plasma generation region 25. The transfer optical system images a part of an image of the target 27 illuminated by the light source on the optical sensor. The optical sensor detects a change in light intensity when the target 27 passes through the detection region 35. The EUV energy sensor 7a is arranged at a position where a part of the EUV light generated in the plasma generation region 25 is incident.

The processor 5 includes a modulation signal generating unit MG and a timing signal generating unit TG.

A gas supply device (not shown) may be arranged to supply a hydrogen gas to the inside of the chamber 2. By the gas supply device, a gas flow corresponding to the supply amount of the hydrogen gas is generated inside the chamber 2. When the target substance contains tin, the tin adhering to an optical element such as the EUV light concentrating mirror 23 may be etched by the hydrogen gas, and the lifetime of the optical element may be extended.

### 2.2 Operation

The master oscillator MO performs laser oscillation and outputs pulse laser light. The output timing of the laser light from the master oscillator MO is defined by a trigger timing signal Sr output from the timing signal generating unit TG to the master oscillator MO. The amplifier PA amplifies the laser light entering from the master oscillator MO.

The optical modulator OM adjusts the energy of the laser light by transmitting the laser light at the transmittance corresponding to the application voltage. The application voltage of the optical modulator OM is defined by a modulation signal output from the modulation signal generating unit MG to the optical modulator OM. The modulation signal includes a feedback control signal FB_{EUV}, which will be described later. The timing for changing the application voltage of the optical modulator OM is defined by a modulation timing signal S_{M} output from the timing signal generating unit TG to the optical modulator OM.

The laser light transmission device 34 guides the laser light 31 entering from the optical modulator OM to the laser light concentrating optical system 22a as the laser light 32. The laser light concentrating optical system 22a concentrates the laser light 32 entering from the laser light transmission device 34 to the plasma generation region 25 as the laser light 33.

The target supply unit 26 supplies the target 27 in a droplet form to the plasma generation region 25 by outputting the target 27 toward the plasma generation region 25. The target timing sensor 4a detects the arrival timing at which the target 27 has reached the detection region 35, and outputs a target detection signal S_{D} indicating the arrival timing to the timing signal generating unit TG.

Based on the target detection signal S_{D} received from the target timing sensor 4a, the timing signal generating unit TG outputs the trigger timing signal S_{T} to the master oscillator MO and outputs the modulation timing signal SM to the optical modulator OM.

The laser light 33 is radiated to the target 27 in the plasma generation region 25. The EUV energy sensor 7a detects an energy E_{EUV} per pulse of the EUV light generated by irradiating the target 27 with the laser light 33, and outputs the detection result to the modulation signal generating unit MG.

The modulation signal generating unit MG outputs a feedback control signal FB_{EUV} for controlling the application voltage of the optical modulator OM based on the energy E_{EUV} of the EUV light received from the EUV energy sensor 7a. For example, when the energy E_{EUV} of the EUV light is lower than a target value, the transmittance of the laser light through the optical modulator OM may be increased by increasing the application voltage of the optical modulator OM. Since the energy of the laser light 31 output from the laser device 3 is increased by increasing the transmittance of the laser light, the laser light 33 applies higher energy to the target 27. Accordingly, the energy E_{EUV} of the EUV light is increased and is allowed to approach the target value.

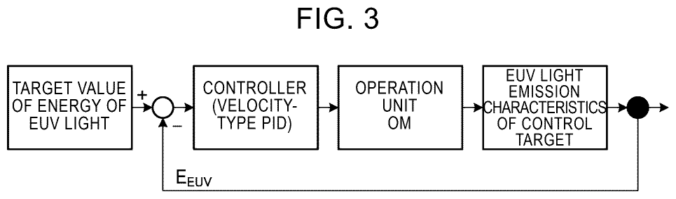

FIG. 3 is a block diagram of energy control of the EUV light according to the comparative example. The processor 5 as a controller outputs a control signal based on a difference between the energy E_{EUV} of the EUV light input to an adder and a target value thereof. The optical modulator OM as an operation unit changes the energy of the laser light 31 in accordance with the control signal. Emission characteristics of the EUV light output from the EUV light generation system as a control target varies in accordance with the energy of the laser light 31. The energy E_{EUV} of the EUV light is measured and fed back negatively to the adder.

The algorithm with which the processor 5 calculates the control signal is, for example, a velocity-type PID algorithm, and the following expression can be used.

$${M}_{n} = KP \cdot {E}_{n} + τ KI {{\sum }^{n}}_{i = 0} {E}_{i} + KD \frac{{E}_{n} - {E}_{n - 1}}{τ} \qquad [ Expression 1 ]$$

Here, M is an operation amount, E is a difference between the energy E_{EUV} of the EUV light and a target value thereof KP is a proportional gain, KI is an integral gain, KD is a differential gain, and τ is a time constant. The indices i, n, and n−1 of the operation variable M and the difference E indicate values for the i-th, n-th, and n−1-th pulses of the EUV light, respectively.

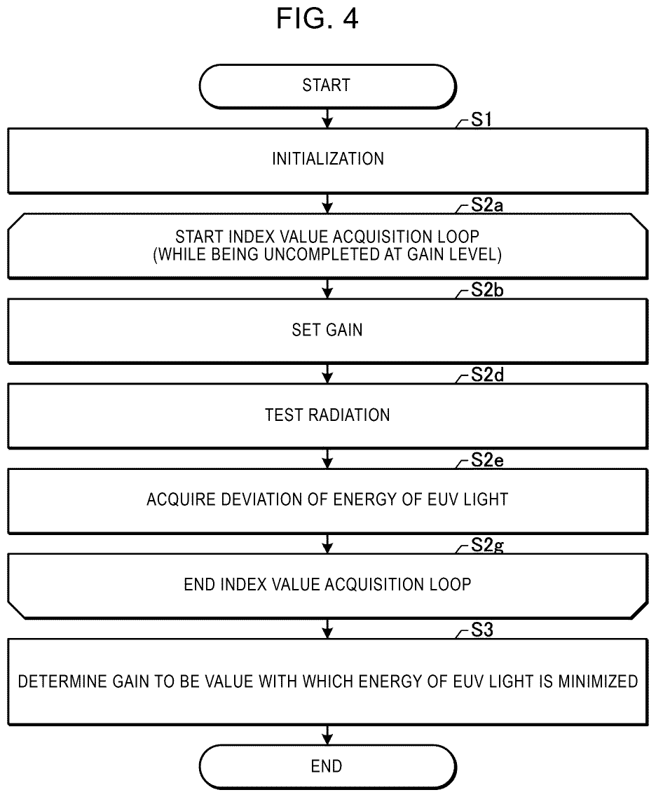

FIG. 4 is a flowchart of control gain determination in the energy control of the EUV light in the comparative example. The processing shown in FIG. 4 is executed without exposure or inspection performed in the EUV light utilization apparatus 6.

In S1, the processor 5 performs initialization of the EUV light generation for control gain determination. The EUV light generation for the control gain determination is preferably performed under a condition in which the effect of the heating of the chamber 2 on the emission characteristics of the EUV light is small, for example, the ratio of the on-time of the EUV light is set to 25% or less. From the viewpoint of securing sufficient data, the number of pulses in one burst oscillation is set to be 1000 to 20000 pulses, and the number of bursts is set to be three or more. Further, the processor 5 enables the energy control of the EUV light described with reference to FIG. 3.

In S2a, the processor 5 starts an index value acquisition loop. The index value acquisition loop is a loop from S2a to S2g, and is executed until the index value acquisition at a plurality of predetermined gain levels is completed.

In S2b, the processor 5 sets the control gain to one of the plurality of gain levels. The gain level may be defined for any one of the proportional gain KP, the integral gain KI, and the differential gain KD, or may be defined for each of two or three. For example, when the plurality of gain levels are determined for each of the proportional gain KP and the integral gain KI, the processes from S2b to S2e are performed for each of the combinations of the gain levels determined for the proportional gain KP and the gain levels determined for the integral gain KI.

In S2d, the processor 5 performs test radiation of the EUV light by controlling the target supply unit 26 and the laser device 3 under the condition set in S1. In S2e, the processor 5 acquires deviation Ed of the energy E_{EUV} of the EUV light through calculation based on the output of the EUV energy sensor 7a. The deviation Ed is an example of the first index value in the present disclosure. The deviation Ed may be an average value of the difference between the energy E_{EUV} of the EUV light and the target value thereof. Alternatively, the deviation Ed may be an average value of a value acquired by dividing a difference between the energy E_{EUV} of the EUV light and the target value thereof by the target value.

When the index value acquisition at all gain levels is completed, the processor 5 ends the index value acquisition loop in S2g.

In S3, the processor 5 determines the control gain in PID control based on the deviation Ed of the energy E_{EUV} of the EUV light. For example, the processor 5 determines the control gain with which the deviation Ed is minimized. After S3, the processor 5 ends processing of the present flowchart.

### 2.3 Problem of Comparative Example

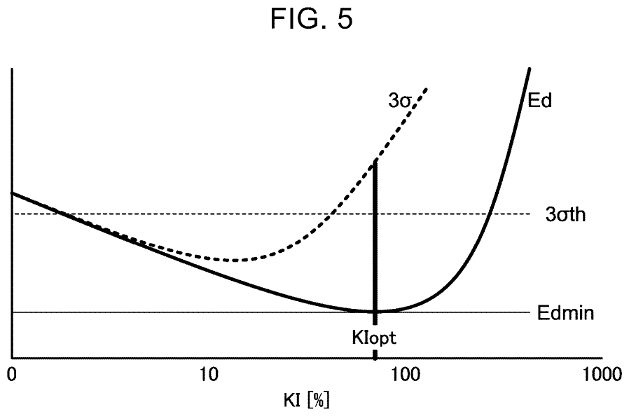

FIG. 5 is a graph showing the relationship between the integral gain KI set in the comparative example, and the deviation Ed and variation 3σ of the energy E_{EUV} of the EUV light. By determining the integral gain KI to a value KIopt with which the deviation Ed becomes a minimum value Edmin and performing PID control, the difference between the energy E_{EUV} of the EUV light and the target value thereof can be minimized.

However, when PID control is performed using KIopt of the integral gain KI determined based on the deviation Ed, the variation 3σ of the energy E_{EUV} of the EUV light may exceed a threshold 3σth that defines an allowable range thereof. In this case, even when the deviation Ed is minimized, the energy E_{EUV} of the EUV light becomes unstable.

### 3. EUV Light Generation System 11a Determining Control Gain in Consideration of Variation 3σ of Energy E_{EUV} of EUV Light

### 3.1 Configuration and Operation

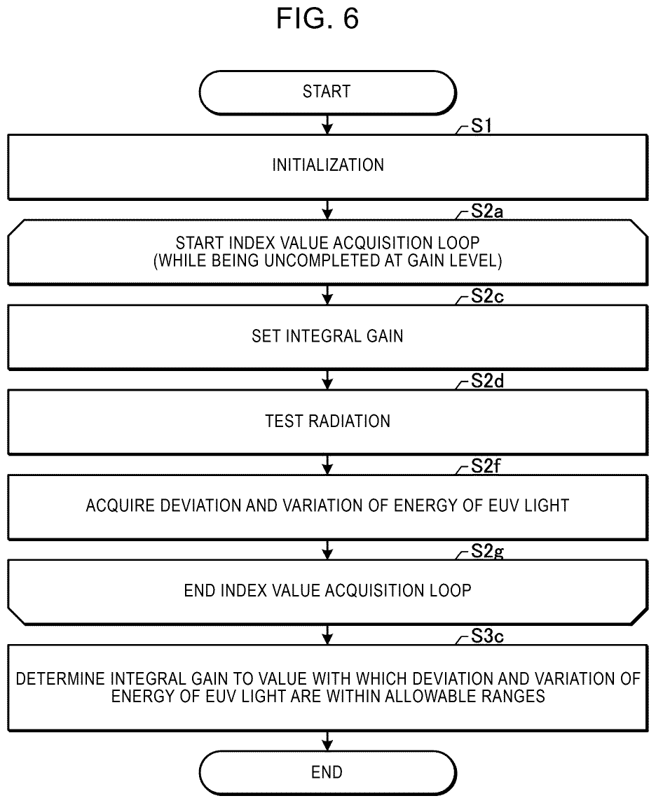

FIG. 6 is a flowchart of control gain determination in the energy control of the EUV light in a first embodiment. The configuration of the first embodiment is similar to that of the comparative example. In the first embodiment, processes of S2c, S2f, and S3c are performed in place of the processes of S2b, S2e, and S3 in FIG. 4, respectively.

In S2c, for example, the processor 5 sets the integral gain KI to one of a plurality of gain levels. The gain level of the integral gain KI may be determined to be, for example, 2%, 4%, 10%, 20%, 40%, 60%, 80%, 100%, 150%, or 200%, or may be determined by an initial value, an increase rate, and a final value. Alternatively, an initial value, an increase value, and an increase count may be specified. By repeating the index value acquisition loop including S2c, the integral gain KI is set sequentially to a plurality of values, and the index value acquisition is performed for each of the values of the integral gain KI. In determining the integral gain KI, the proportional gain KP and the differential gain KD may be fixed without defining a plurality of gain levels for the proportional gain KP and the differential gain KD. Alternatively, the proportional gain KP or the differential gain KD may be changed as needed, such as to suppress hunting or improve transient responsiveness. When the proportional gain KP or the differential gain KD is changed, the index value may be acquired again for each of the values of the integral gain KI.

In S2f, the processor 5 acquires, based on the output of the EUV energy sensor 7a, the deviation Ed and the variation 3σ of the energy E_{EUV} of the EUV light. The variation 3σ is an example of the second index value in the present disclosure. The variation 3σ may be a standard deviation of the energy E_{EUV} of the EUV light, a value of the variance which is the square thereof, or a value acquired by multiplying any of them by a positive number, for example, three. The small variation 3σ indicates that the energy E_{EUV} of the EUV light is stable.

In S3c, the processor 5 determines the control gain in PID control based on both the deviation Ed and the variation 3σ of the energy E_{EUV} of the EUV light. For example, the processor 5 determines the control gain such that the deviation Ed is within a first allowable range and the variation 3σ is within a second allowable range.

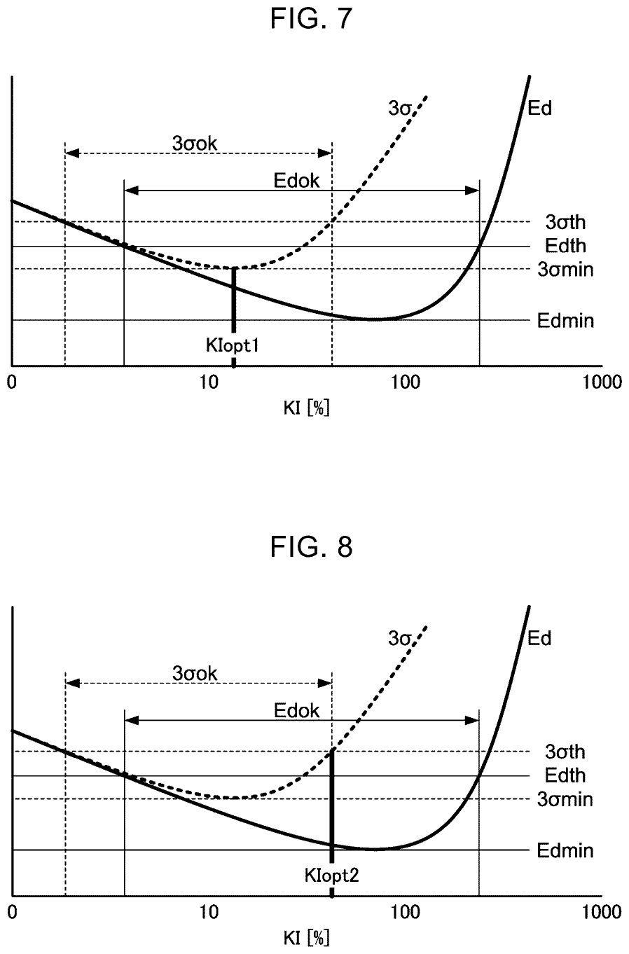

FIG. 7 is a graph showing the relationship between the integral gain KI set in the first embodiment, and the deviation Ed and the variation 3σ of the energy E_{EUV} of the EUV light. The first allowable range of the deviation Ed is set to a range of 0 to a threshold Edth both inclusive, and the second allowable range of the variation 3σ is set to a range of 0 to the threshold 3σth both inclusive. The range of the integral gain KI in which the deviation Ed is within the first allowable range is shown as Edok, and the range of the integral gain KI in which the variation 3σ is within the second allowable range is shown as 3σok. By determining the integral gain KI to be included in both the range Edok and the range 3σok, as described in S3c of FIG. 6, the deviation Ed becomes within the first allowable range and the variation 3σ becomes within the second allowable range. The integral gain KI determined in this way has a value smaller than the value KIopt (see FIG. 5) of the integral gain KI with which the deviation Ed becomes the minimum value Edmin.

The integral gain KI in the first embodiment is determined to be a value that maximizes the difference between the variation 3σ and the threshold 3σth in the region of being included in both the range Edok and the range 3σok. In the example shown in FIG. 7, the integral gain KI is determined to be a value KIopt1 with which the variation 3σ becomes the minimum value 3σmin. In the present disclosure, the maximum or minimum does not mean an exact maximum or minimum, and an error within 10%, preferably within 5% is allowed. Instead of the variation 3σ, a value indicating the stability of the energy E_{EUV} of the EUV light may be used. The stability may be indicated by the inverse of the variation 3σ. When the magnitude relation between the value of the variation 3σ and the value indicating the stability is opposite, that is, when the value indicating the stability is larger as the value of the variation 3σ is smaller, the integral gain KI is determined so that the value indicating the stability is maximized.

### 3.2 Modification

In FIGS. 6 and 7, description is provided on the case in which the variation 3σ of the energy E_{EUV} of the EUV light is the second index value. However, the present disclosure is not limited thereto. For example, when the energy E_{EUV} of the EUV light fluctuates and the difference from the target value increases, the application voltage of the optical modulator OM is adjusted by the feedback control signal FB_{EUV}. Therefore, instead of the variation 3σ of the energy E_{EUV} of the EUV light, the variation of the application voltage of the optical modulator OM may be used as the second index value. Further, for example, the variation of the energy E_{EUV} of the EUV light is related to the variation of the conversion efficiency of the energy E_{L} of the laser light to the energy E_{EUV} of the EUV light. Therefore, instead of the variation 3σ of the energy E_{EUV} of the EUV light, the variation of the conversion efficiency may be used as the second index value. The conversion efficiency may be calculated by the processor 5 based on the output of the laser energy sensor LS and the output of the EUV energy sensor 7a.

### 3.3 Effect

According to the first embodiment, the EUV light generation system 11a includes the target supply unit 26, the laser device 3, the EUV energy sensor 7a, the optical modulator OM, and the processor 5. The target supply unit 26 supplies the target 27. The laser device 3 irradiates the target 27 with the laser light 33. The EUV energy sensor 7a detects the energy E_{EUV} of the EUV light generated by irradiating the target 27 with the laser light 33. The optical modulator OM adjusts the energy of the laser light 33. The processor 5 adjusts the optical modulator OM by PID control based on the output of the EUV energy sensor 7a. A control method of the EUV light generation system 11a includes that the processor 5 acquires the first index value for the output of the EUV energy sensor 7a and the second index value being different from the first index value, and determines the control gain in PID control based on the first and second index values.

According to the above, since the control gain is determined based on the two index values, the EUV light generation system 11a can be appropriately operated.

According to the first embodiment, the control gain is determined such that the first index value is within the first allowable range and the second index value is within the second allowable range.

According to the above, even when both of the first and second index values cannot be set to the optimum values, the EUV light generation system 11a can be appropriately operated by setting both of the first and second index values to be within the respective allowable ranges.

According to the first embodiment, the control gain is determined such that the difference between the second index value and the threshold defining the second allowable range is maximized.

According to the above, the EUV light generation system 11a can be appropriately operated by setting the control gain such that the second index value is the optimum value among the control gains allowing the first and second index values to be within the respective allowable ranges.

According to the first embodiment, the first index value is the deviation Ed of the output of the EUV energy sensor 7a.

According to the above, the deviation Ed of the energy E_{EUV} of the EUV light can be set to be within the allowable range, and the EUV light generation system 11a can be appropriately operated.

According to the first embodiment, the second index value is the variation 3σ of the output of the EUV energy sensor 7a.

According to the above, the EUV light generation system 11a can be appropriately operated by setting the control gain such that the variation 3σ of the energy E_{EUV} of the EUV light becomes the optimum value.

According to the first embodiment, the optical modulator OM is arranged on the optical path of the laser light, and the processor 5 is configured to control the application voltage of the optical modulator OM based on the output of the EUV energy sensor 7a. The second index value is the variation of the application voltage.

According to the above, it is possible to suppress the variation 3σ of the energy E_{EUV} of the EUV light from being out of the allowable range by using the variation of the application voltage controlled based on the energy E_{EUV} of the EUV light as the index.

According to the first embodiment, the EUV light generation system 11a further includes the laser energy sensor LS arranged on an optical path of the laser light. The processor 5 is configured to calculate, based on the output of the laser energy sensor LS and the output of the EUV energy sensor 7a, the conversion efficiency from the energy E_{L} of the laser light to the energy E_{EUV} of the EUV light. The second index value is the variation of the conversion efficiency.

According to the above, it is possible to suppress the variation 3σ of the energy E_{EUV} of the EUV light from being out of the allowable range by using, as the index, the variation of the conversion efficiency, which is the ratio of the energy E_{EUV} of the EUV light to the energy E_{L} of the laser light.

According to the first embodiment, the control gain includes the integral gain KI, and the processor 5 sequentially sets the integral gain KI to the plurality of values, and acquires the first and second index values for each of the values of the integral gain KI.

According to the above, it is possible to find the appropriate value of the integral gain KI by sequentially setting the integral gain KI and performing the test radiation, and to bring the first and second index values closer to the respective target values.

According to the first embodiment, the control gain includes the proportional gain KP, the integral gain KI, and the differential gain KD, and the processor 5 sequentially sets the integral gain KI to the plurality of values while fixing the proportional gain KP and the differential gain KD, and acquires the first and second index values for each of the values of the integral gain KI.

According to the above, the gain adjustment can be efficiently performed by fixing the proportional gain KP and the differential gain KD.

According to the first embodiment, the first index value is the deviation Ed of the output of the EUV energy sensor 7a, and the processor 5 determines the integral gain KI to be the value smaller than the value KIopt of the integral gain KI with which the deviation Ed is minimized.

When the integral gain KI is determined to be the value KIopt with which the deviation Ed of the energy E_{EUV} of the EUV light is minimized, there may be a case that the variation 3σ of the energy E_{EUV} of the EUV light exceeds the allowable range with a high gain. However, by setting the integral gain KI smaller than the value KIopt, the variation 3σ can be suppressed.

In other respects, the first embodiment is similar to the comparative example.

### 4. EUV Light Generation System 11a Determining Control Gain to Minimize Deviation Ed of Energy E_{EUV} of EUV Light

### 4.1 Configuration and Operation

FIG. 8 is a graph showing the relationship between the integral gain KI set in a second embodiment, and the deviation Ed and the variation 3σ of the energy E_{EUV} of the EUV light. The configuration of the second embodiment is similar to that of the comparative example and the first embodiment, and the flowchart of the control gain determination is similar to that of the first embodiment. The integral gain KI in the second embodiment is determined to be a value that maximizes the difference between the deviation Ed and the threshold Edth in the region of being included in both the range Edok and the range 3σok. In the example shown in FIG. 8, since the deviation Ed monotonically decreases in the region included in both the range Edok and the range 3σok, the difference between the deviation Ed and the threshold Edth is maximized by determining the integral gain KI to a maximum value KIopt2 in the region.

In FIG. 8, description is provided on the case in which the deviation Ed of the energy E_{EUV} of the EUV light is the first index value and the variation 3σ of the energy E_{EUV} of the EUV light is the second index value. However, the present disclosure is not limited thereto. Instead of the variation 3σ of the energy E_{EUV} of the EUV light, the variation of the application voltage of the optical modulator OM may be used as the second index value, or the variation in the conversion efficiency may be used as the second index value. Further, a value indicating stability may be used instead of the variation.

### 4.2 Effect

According to the second embodiment, the control gain is determined such that the difference between the first index value and the threshold defining the first allowable range is maximized.

According to the above, the EUV light generation system 11a can be appropriately operated by setting the control gain such that the first index value is the optimum value among the control gains allowing the first and second index values to be within the respective allowable ranges.

According to the second embodiment, the first index value is the deviation Ed of the output of the EUV energy sensor 7a.

According to the above, the EUV light generation system 11a can be appropriately operated by setting the control gain such that the deviation Ed of the energy E_{EUV} of the EUV light becomes the optimum value.

According to the second embodiment, the second index value is the variation 3σ of the output of the EUV energy sensor 7a.

According to the above, the variation 3σ of the energy E_{EUV} of the EUV light can be set to be within the allowable range, and the EUV light generation system 11a can be appropriately operated.

In other respects, the second embodiment is similar to the first embodiment.

### 5. Timing of Control Gain Determination Processing

The control gain determination processing shown in FIG. 6 may be performed at any of the following timings (a) to (d).

(a) After replacement of the laser device 3, for example, after replacement of the main pulse laser and before exposure or inspection in the EUV light utilization device 6

Even if the characteristics of the laser light 31 change due to individual differences of the laser device 3 when the laser device 3 replaced, the EUV light generation system 11a can be appropriately operated by redetermining the control gain according to the present disclosure.

(b) After changing the light intensity at the position where the target 27 is irradiated with the laser light 33 and before exposure or inspection in the EUV light utilization apparatus 6

Even if the light intensity of the laser light 33 is changed, the EUV light generation system 11a can be appropriately operated by redetermining the control gain according to the present disclosure.

(c) After changing a setting value of the size of the target 27 and before exposure or inspection in the EUV light utilization apparatus 6

Even if the optimum value of the velocity of the target 27 or the light intensity of the laser light 33 is changed by changing the setting value of the size of the target 27, the EUV light generation system 11a can be appropriately operated by redetermining the control gain according to the present disclosure.

(d) After changing gas flow around the target 27 and before exposure or inspection in the EUV light utilization apparatus 6

Even if the trajectory of the target 27 is changed due to the change of the gas flow, the EUV light generation system 11a can be appropriately operated by redetermining the control gain according to the present disclosure.

### 6. Others

### 6.1 Example of EUV Light Utilization Apparatus 6

FIG. 9 shows the configuration of the exposure apparatus 6a connected to the EUV light generation system 11a. The exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11a. The workpiece irradiation unit 609 images the EUV light reflected by the mask table MT onto a workpiece (not shown) arranged on a workpiece table WT via the reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 10 shows the configuration of the inspection apparatus 6b connected to the EUV light generation system 11a. The inspection apparatus 6b as the EUV light utilization apparatus 6 (see FIG. 1) includes an illumination optical system 603 and a detection optical system 606. The illumination optical system 603 reflects the EUV light incident from the EUV light generation system 11a to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. Inspection for a defect of the mask 605 is performed based on the image of the mask 605 obtained by the above-described steps, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 6.2 Processor 5

The processor 5 may be physically configured as hardware to execute various processes included in the present disclosure. For example, the processor 5 may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor 5 may be programmed as software to execute the various processes included in the present disclosure. For example, the processor 5 may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 6.3 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A control method of an extreme ultraviolet light generation system,
the extreme ultraviolet light generation system including:
a target supply unit configured to supply a target;
a laser device configured to irradiate the target with laser light;
an EUV energy sensor configured to detect an energy of extreme ultraviolet light generated by the target being irradiated with the laser light;
an optical adjuster configured to adjust an energy of the laser light; and
a processor configured to adjust the optical adjuster by PID control based on output of the EUV energy sensor, and
the processor acquiring a first index value for the output of the EUV energy sensor and a second index value different from the first index value and determining a control gain in the PID control based on the first and second index values.

2. The control method according to claim 1,
wherein the control gain is determined such that the first index value is within a first allowable range and the second index value is within a second allowable range.

3. The control method according to claim 2,
wherein the control gain is determined such that a difference between the second index value and a threshold defining the second allowable range is maximized.

4. The control method according to claim 3,
wherein the first index value is a deviation of the output of the EUV energy sensor.

5. The control method according to claim 4,
wherein the second index value is a variation of the output of the EUV energy sensor.

6. The control method according to claim 4,
wherein the optical adjuster is an optical modulator arranged on an optical path of the laser light,
the processor is configured to control an application voltage of the optical modulator based on the output of the EUV energy sensor, and
the second index value is a variation of the application voltage.

7. The control method according to claim 4,
wherein the extreme ultraviolet light generation system further includes a laser energy sensor arranged on an optical path of the laser light,
the processor is configured to calculate a conversion efficiency from the energy of the laser light to the energy of the extreme ultraviolet light based on output of the laser energy sensor and the output of the EUV energy sensor, and
the second index value is a variation of the conversion efficiency.

8. The control method according to claim 2,
wherein the control gain is determined such that a difference between the first index value and a threshold defining the first allowable range is maximized.

9. The control method according to claim 8,
wherein the first index value is a deviation of the output of the EUV energy sensor.

10. The control method according to claim 9,
wherein the second index value is a variation of the output of the EUV energy sensor.

11. The control method according to claim 1,
wherein the control gain includes an integral gain, and
the processor sequentially sets the integral gain to a plurality of values and acquires the first and second index values for each of the values of the integral gain.

12. The control method according to claim 1,
wherein the control gain includes a proportional gain, an integral gain, and a differential gain, and
the processor sequentially sets the integral gain to a plurality of values while fixing the proportional gain and the differential gain and acquires the first and second index values for each of the values of the integral gain.

13. The control method according to claim 1,
wherein the first index value is a deviation of the output of the EUV energy sensor, and
the processor determines the control gain to be a value smaller than the control gain with which the deviation is minimized.

14. The control method according to claim 1,
wherein the processor acquires the first and second index values after the laser device is replaced, and determines the control gain.

15. The control method according to claim 1,
wherein the processor acquires the first and second index values after changing light intensity at a position where the target is irradiated with the laser light, and determines the control gain.

16. The control method according to claim 1,
wherein the processor acquires the first and second index values after changing a setting value of a size of the target, and determines the control gain.

17. The control method according to claim 1,
wherein the processor acquires the first and second index values after changing gas flow around the target, and determines the control gain.

18. An extreme ultraviolet light generation system, comprising:
a target supply unit configured to supply a target;
a laser device configured to irradiate the target with laser light;
an EUV energy sensor configured to detect an energy of extreme ultraviolet light generated by the target being irradiated with the laser light;
an optical adjuster configured to adjust an energy of the laser light; and
a processor configured to adjust the optical adjuster by PID control based on output of the EUV energy sensor, and acquiring a first index value for the output of the EUV energy sensor and a second index value different from the first index value and determining a control gain in the PID control based on the first and second index values.

19. An electronic device manufacturing method, comprising:
generating extreme ultraviolet light using an extreme ultraviolet light generation system;
outputting the extreme ultraviolet light to an exposure apparatus; and
exposing a photosensitive substrate to the extreme ultraviolet light in the exposure apparatus to manufacture an electronic device,
the extreme ultraviolet light generation system including:
a target supply unit configured to supply a target;
a laser device configured to irradiate the target with laser light;
an EUV energy sensor configured to detect an energy of the extreme ultraviolet light generated by the target being irradiated with the laser light;
an optical adjuster configured to adjust an energy of the laser light; and
a processor configured to adjust the optical adjuster by PID control based on output of the EUV energy sensor, and acquiring a first index value for the output of the EUV energy sensor and a second index value different from the first index value and determining a control gain in the PID control based on the first and second index values.

20. An electronic device manufacturing method, comprising:
inspecting a defect of a mask by irradiating the mask with extreme ultraviolet light generated by an extreme ultraviolet light generation system;
selecting a mask using a result of the inspection; and
exposing and transferring a pattern formed on the selected mask onto a photosensitive substrate,
the extreme ultraviolet light generation system including:
a target supply unit configured to supply a target;
a laser device configured to irradiate the target with laser light;
an EUV energy sensor configured to detect an energy of the extreme ultraviolet light generated by the target being irradiated with the laser light;
an optical adjuster configured to adjust an energy of the laser light; and
a processor configured to adjust the optical adjuster by PID control based on output of the EUV energy sensor, and acquiring a first index value for the output of the EUV energy sensor and a second index value different from the first index value and determining a control gain in the PID control based on the first and second index values.
